(19) United States
(12) Patent Application Publication
(10) Pub. No.: US 2007/0102289 A1
(43) Pub. Date: May 10, 2007

(54) Sputtering target material

(76) Inventors: Kazuteru Kato, Fukuoka (JP); Takashi Kubota, Fukuoka (JP); Hiroshi Kimura, Fukuoka (JP); Yoshinori Matsuura, Saitama (JP); Kenji Matsuzaki, Saitama (JP)

Correspondence Address: ROBERTS & ROBERTS, LLP;ATTORNEYS AT LAW, P.O. BOX 484, PRINCETON, NJ, 08542-0484, US

(21) Appl. No.: 10/580,222

(22) PCT Filed: Jul. 8, 2005
(86) PCT No.: PCT/JP05/12657

§ 371 Date: May 19, 2006

(30) Foreign Application Priority Data
Jul. 9, 2004 (JP) P2004-203623

(51) Int. Cl. C23C 14/00

(52) U.S. Cl. 204/298.12

(57) ABSTRACT

The provided is a sputtering target material that is made not to cause an arcing phenomenon and splash phenomenon at the time of sputtering as completely as possible. A portion to be used for sputtering of the sputtering target material is subjected to a friction stir processing. Even with a sputtering target material made of a carbon-containing aluminum alloy or a large-sized sputtering target material, the arcing phenomenon and the splash phenomenon at the time of sputtering can be certainly suppressed.

### TECHNICAL FIELD

The present invention relates to a sputtering target material (hereinafter sometimes simply referred to as a target material), in particular, to an aluminum alloy sputtering target material that suppresses an arcing phenomenon and a splash phenomenon occurring at the time of sputtering.

### BACKGROUND ART

In these years, sputtering target materials have been used in the fields of FPDs (Flat Panel Display), recording media, semiconductor devices and the like. Additionally, in the FPD field, sputtering target materials themselves are increasing in size with an increase in screen size.

As sputtering target materials used in various fields, target materials having various compositions and qualities are known; however, irrespective of the differences in the compositions thereof, the sputtering target materials are required to have such properties that neither the arcing phenomenon nor the splash phenomenon occurs at the time of sputtering.

The arcing phenomenon used herein means an abnormal discharge occurring at the time of sputtering. Occurrence of the arcing phenomenon inhibits a stable formation of a thin film with sputtering. On the other hand, the splash phenomenon means abnormal splashing droplets, which are generated from the target material at the time of sputtering and adhered to a substrate or the like. Such abnormal splashing droplets are larger in size than the usual sputter particles, and adhesion of such droplets to a substrate inhibits a uniform formation of a thin film, for example, in such a way that such abnormal splashing droplets cause short-circuiting or breaking of wirings.

For the purpose of suppressing the arcing phenomenon and the splash phenomenon, it has been attempted to make the structure of a sputtering target material fine and homogeneous. With a target material homogeneous and fine in structure having no defects such as vacancies, the arcing phenomenon and the splash phenomenon at the time of sputtering are suppressed to permit attaining a higher film formation rate.

As a method for producing a sputtering target material, in general, a gravity casting or the powder metallurgy method is adopted. In addition, as affairs now stand, for the purpose of obtaining a target material with homogeneous and fine structure, improvement of the method for producing the target material is resorted to.

However, because of various compositions available for the target material and required adaptation to the recent size increase, there have started to appear such cases where only the structure modification provided by devising the method for producing target materials cannot sufficiently suppress the arcing phenomenon and the splash phenomenon. For example, when the material quality of the sputtering target material is a composite material or the like, it cannot always be realized to a sufficiently satisfactory level to disperse dispersion particles in the matrix homogeneously and finely only by resorting to improvement of the production method (see, for example, Patent Document 1).

Patent Document 1: Japanese Patent Laid-Open No. 2003-3258.

### DISCLOSURE OF THE INVENTION

### Problems to be Solved by the Invention

The present invention has been achieved under the above described circumstances. Thus, an object of the present invention is to provide a sputtering target material with structure modified to be homogeneous and fine so that the arcing phenomenon and the splash phenomenon at the time of sputtering may not be caused therein as completely as possible.

### MEANS FOR SOLVING THE PROBLEMS

For the purpose of solving the above described problems, the present invention is characterized in that a portion to be used for sputtering in a sputtering target material is subjected to a friction stir processing. The friction stir processing as referred to in the present invention means a structure modification processing carried out by means of a friction stir welding (FSW) method. Specifically, the friction stir processing means a processing in which, a probe harder than the target material in material quality is made to abut a portion to be used for sputtering in a target material, a relative cyclic movement (for example, a movement such that the probe travels while it is being rotated) between the probe and the portion concerned is made to occur, and the thus generated friction heat creates a plastic flow in the portion concerned. The structure of the portion in which the plastic flow has been created with the friction stir processing becomes more homogeneous and finer than the structure of the portion as observed before the processing. Consequently, the sputtering target material according to the present invention enables to certainly suppress the arcing phenomenon and the splash phenomenon at the time of sputtering.

More specific conditions for the friction stir processing are such that a traveling distance of the probe in one rotation is preferably set at 0.45 mm to 1.40 mm. When the traveling distance is smaller than 0.45 mm/rotation, burrs and pinholes tend to be easily generated, and the productivity is also degraded. On the other hand, when the traveling distance exceeds 1.40 mm/rotation, there is developed a strong tendency for burrs and pinholes to be easily generated, and sometimes the probe itself bends and gets damaged, or a motor for use in the friction stir processing is overloaded and burns out. When burrs and pinholes are generated in the sputtering target material in the course of the friction stir processing, the arcing phenomenon and the splash phenomenon at the time of sputtering tend to easily occur to negate the advantageous effect of the friction stir processing of the present invention. Additionally, it is preferable that the target material after having been subjected to the friction stir processing undergoes an annealing processing if need arises, because by performing this annealing processing, the structure of the target material can be made more uniform and the internal stress is also alleviated, and consequently warping at the time of bonding to a backing plate or the like is also suppressed. The annealing processing conditions such as, for example, the annealing temperature and the annealing processing time can be appropriately adjusted in consideration of the material quality of the target material.

Additionally, the friction stir processing of the present invention is absolutely independent of the material quality of the sputtering target material, in particular, the material quality due to the production method, and consequently can certainly suppress the arcing phenomenon and the splash phenomenon even if the target material is a sintered material or a cast material.

The friction stir processing of the present invention is preferably applied to a target material made of an aluminum alloy, and further desirably to a target material made of a carbon-containing aluminum alloy. Aluminum alloy sputtering target materials, recently attracting attentions as wiring materials for liquid crystal displays and hitting the market as large-sized target materials having a large area, are stringently required to suppress the arcing phenomenon and the splash phenomenon that are fundamental properties of the target materials. The sputtering target material according to the present invention can satisfactorily suppress the arcing phenomenon and the splash phenomenon to permit stable sputtering, even if the target material is made of an aluminum alloy. A carbon-containing aluminum alloy can be referred to as a particle dispersion-type composite material, and it is not easy to make the structure of such a material homogeneous and fine, so that there is a tendency to make it difficult to suppress the arcing phenomenon and the splash phenomenon to a practically satisfactory level. However, application of the friction stir processing of the present invention makes it possible to satisfactorily suppress the arcing phenomenon and the splash phenomenon even if the target material is made of a carbon-containing aluminum alloy.

Additionally, the present invention makes it possible to certainly suppress the arcing phenomenon and the splash phenomenon even when a sputtering target material is made of an aluminum alloy containing any one or more elements selected from nickel, cobalt and iron. A target material made of an aluminum alloy having such a composition can form a thin film permitting direct ohmic contact with an ITO film; and when such a thin film is formed directly on silicon, mutual diffusion between silicon and aluminum does not occur, and wiring with low specific resistance and excellent heat resistance can be formed. On the other hand, a sputtering target material made of an aluminum alloy having such a composition is known to have a structure in which a carbide and an intermetallic compound are dispersed in the aluminum matrix phase; in the sputtering target material of the present invention, such a carbide and an intermetallic compound are dispersed homogeneously and finely in the aluminum matrix phase, and the arcing phenomenon and the splash phenomenon are thereby made to hardly occur. Examples of such an aluminum alloy may include, for example, an aluminum-carbon-nickel alloy and an aluminum-carbon-nickel-cobalt alloy; the composition of such an alloy can be such that the content of at least one or more elements selected from nickel, cobalt and iron is 0.5 to 7.0 at %, the content of carbon is 0.1 to 3.0 at %, and the balance is aluminum.

### ADVANTAGEOUS EFFECT OF THE INVENTION

As described above, the sputtering target material according to the present invention is made to have a portion to be used for sputtering that is homogeneous and fine in structure irrespective of the composition, the size and the material quality differences due to the production method of the target material, and consequently the sputtering target material of the present invention can certainly suppress the arcing phenomenon and the splash phenomenon at the time of sputtering. The present invention is particularly effective for a sputtering target material made of an aluminum alloy to be used for liquid crystal displays progressively growing in area size.

### BRIEF DESCRIPTION OF THE DRAWINGS

FIG. 1 is a schematic view illustrating a friction stir processing;

FIG. 2 is a micrograph (magnification factor: 500) based on SEM observation of the surface of a target material of a comparative example;

FIG. 3 is another micrograph (magnification factor: 500) based on SEM observation of the surface of the target material of the comparative example;

FIG. 4 is a micrograph (magnification factor: 500) based on SEM observation of the surface of a target material of an example;

FIG. 5 is another micrograph (magnification factor: 500) based on SEM observation of the surface of the target material of the example; and

FIG. 6 is a schematic sectional view of a stir rod.

### BEST MODE FOR CARRYING OUT THE INVENTION

Preferred embodiments of the present invention are described below on the basis of an example and a comparative example.

### Example

The target materials of the present example and comparative example were made of a carbon-containing aluminum alloy produced in a manner as follows. First, an aluminum having a purity of 99.99% was put in a carbon crucible (purity: 99.9%), and the aluminum was melted via heating within a temperature range from 1600 to 2500° C. This melting of the aluminum with the carbon crucible was carried out in an argon-gas atmosphere with a pressure of the argon-gas atmosphere set at atmospheric pressure. The aluminum was maintained at the melting temperature for about 5 minutes to produce an aluminum-carbon alloy in the carbon crucible, and thereafter, the molten alloy was poured into a carbon casting mold and allowed to stand under natural cooling to cast an ingot.

The ingot of the aluminum-carbon alloy cast with the carbon mold was taken out, charged with the aluminum having a purity of 99.99% and nickel each in a predetermined amount, then put in a remelting carbon crucible, remelted via heating at 800° C., and stirred for about 1 minute. This remelting was also carried out in the argon-gas atmosphere in the pressure of the argon-gas atmosphere set at atmospheric pressure. After stirring, the molten alloy was cast into a water-cooled copper casting mold to produce a plate-like ingot. From the thus obtained ingot, with a rolling machine, a 20 mm thick×400 mm wide×600 mm long plate-like target material was formed.

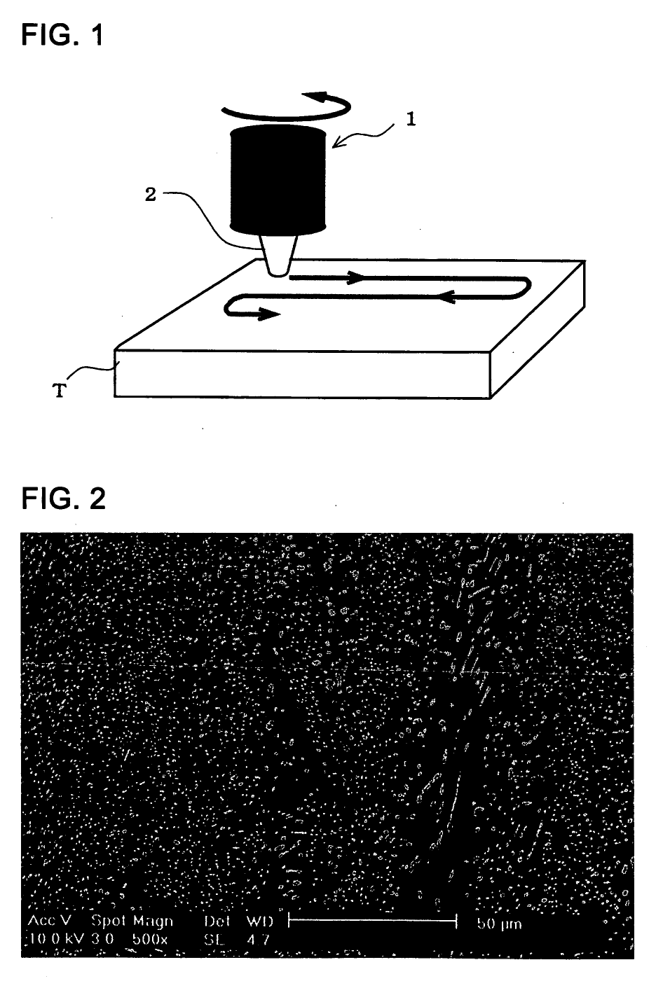

The target material of the present example was prepared by applying the friction stir processing to one side of a target material produced as described above. As shown in FIG. 1, the friction stir processing was carried out by disposing a stir rod 1 of a commercially available friction stir welding apparatus directly on the upper side of a target material T. A tip 2 (made of steel) of the stir rod 1 was made to travel almost over the whole area of an upper side of the target material T at a predetermined rotation speed and a predetermined traveling speed.

The friction stir processing is specifically described as follows. The stir rod used had a sectional dimension shown in FIG. 6. The stir rod 1 was controlled so as to have a rotation speed of 500 rpm and a traveling speed of 300 mm/min (0.6 mm/rotation). The tip of the stir rod was made to penetrate into the target material at a depth of about 12 mm. On completion of the friction stir processing of almost the whole area of the one side of the target material, the target material was reversed and the friction stir processing was also applied to the unprocessed side under the same conditions. Consequently, the target material of the example underwent the friction stir processing in almost the whole target material in such a way that the friction stir processing was also found to be applied even along the depth direction over the whole depth. For comparison with the example, a target material without undergoing the FSW processing was used as a comparative example.

The target materials of the above described example and comparative example were investigated with respect to an SEM observation of the surface thereof, measurement of the surface roughness thereof, and the arcing properties and splash properties thereof.

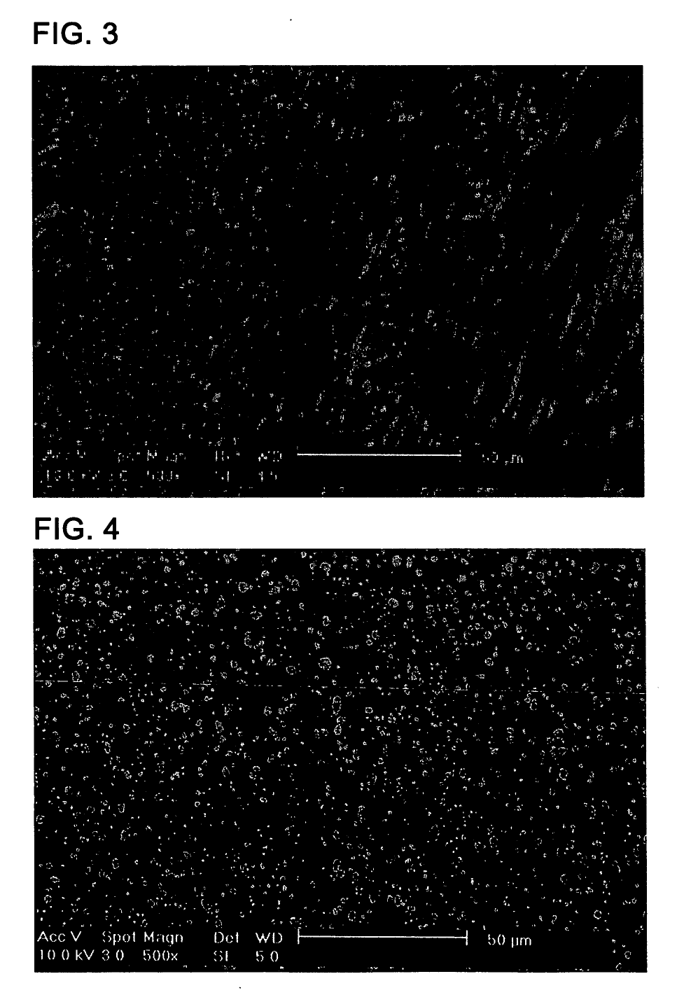

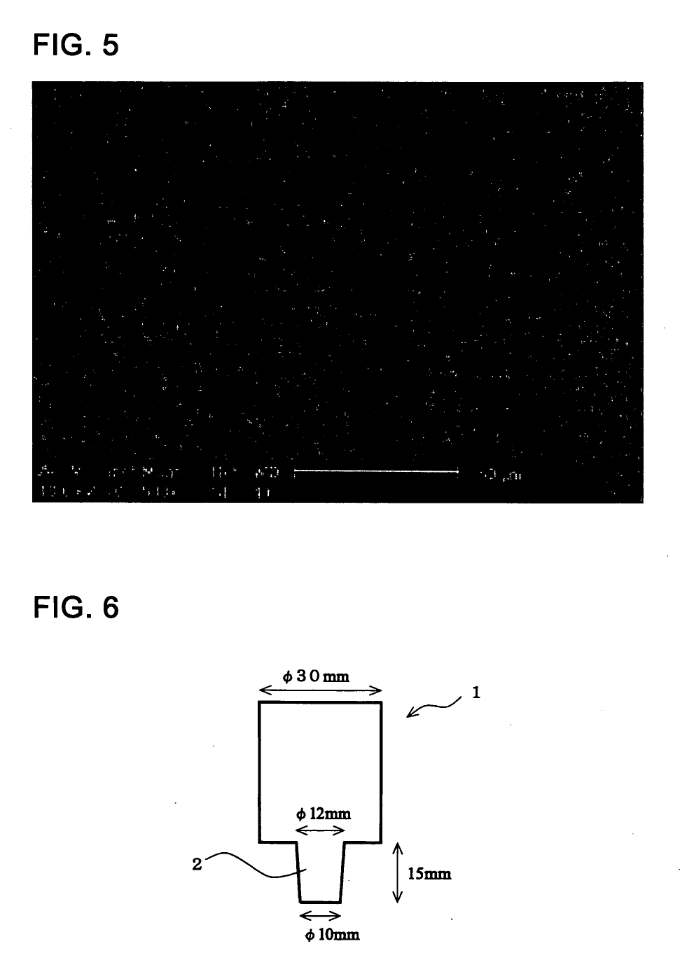

FIGS. 2 and 3 show results of the SEM observation of the comparative example, and FIGS. 4 and 5 show results of the SEM observation of the example. In the comparative example as shown in FIG. 2, needle-like blackish precipitates appeared, and the precipitates were found to be a carbide Al₄C₃ (the black needle-like precipitates, seen in the center of the micrograph of FIG. 2, of about 50 μm in length). The portions seen as white spots in FIGS. 2 and 3 were found to be precipitates of an intermetallic compound Al₃Ni, and as shown in FIG. 3, it was observed a large number of portions in which the Al₃Ni precipitates were distributed in stripes. On the other hand, in the example associated with FIGS. 4 and 5, the carbide Al₄C₃ was not observed in a state of such relatively large precipitates as observed in FIG. 2, but was observed in a state of uniform dispersion as a whole; and as for the intermetallic compound Al₃Ni, a state that the intermetallic compound was distributed in stripes as in the comparative example was not substantially identified, but a state that the intermetallic compound was distributed uniformly as a whole was identified.

Next, results obtained for the arcing properties are described below. The arcing properties were determined as follows: a circular disc (203.2 mm in diameter×10 mm in thickness) of sputtering target was cut out of each of the above described plate-like target materials, disposed in a commercially available sputtering apparatus (MSL-464, manufactured by Tokki Corp.), sputtering was carried out with an input electric power of 12 W/cm² for a predetermined period of time, and the number of times of abnormal discharge the above described apparatus counted in the course of the sputtering processing served to determine the arcing properties. Consequently, in the comparative example, the abnormal discharge occurred 4447 times within a sputtering period of 3.5 hours; on the other hand, in the example, the abnormal discharge occurred only 250 times within a sputtering period of 3.5 hours.

Finally, results obtained for the splash properties are described below. One hour of sputtering was carried out under the same conditions as in the case of the above described arcing properties to form a thin film of an Al—Ni—C alloy on a glass substrate. Thereafter, the surface of the thin film was observed to investigate whether splashes (abnormal droplets) of 10 μm or more were present or not. Consequently, a large number of abnormal droplets were identified with the target material of the comparative example, but absolutely no abnormal droplets of 10 μm or more were identified in the example.

1. A sputtering target material, wherein a portion to be used for sputtering of the sputtering target material is subjected to a friction stir processing.

2. The sputtering target material according to claim 1, wherein the sputtering target material is made of an aluminum alloy.

3. The sputtering target material according to claim 2, wherein the aluminum alloy comprises carbon.

4. The sputtering target material according to claim 2, comprising any one or more elements selected from nickel, cobalt and iron.

5. The sputtering target material according to claim 1, wherein the sputtering target material is a sintered material or a cast material.

6. The sputtering target material according to claim 3, comprising any one or more elements selected from nickel, cobalt and iron.

7. The sputtering target material according to claim 2, wherein the sputtering target material is a sintered material or a cast material.

8. The sputtering target material according to claim 3, wherein the sputtering target material is a sintered material or a cast material.

9. The sputtering target material according to claim 4, wherein the sputtering target material is a sintered material or a cast material.

10. The sputtering target material according to claim 6, wherein the sputtering target material is a sintered material or a cast material.

11. A method for processing a sputtering target material which comprises subjecting a portion of a sputtering target material to a friction stir processing.

12. The method according to claim 11, wherein the sputtering target material is made of an aluminum alloy.

13. The method according to claim 12, wherein the aluminum alloy comprises carbon.

14. The method according to claim 12, comprising any one or more elements selected from nickel, cobalt and iron.

15. The method according to claim 11, wherein the sputtering target material is a sintered material or a cast material.

16. The method according to claim 13, comprising any one or more elements selected from nickel, cobalt and iron.

17. The method according to claim 12, wherein the sputtering target material is a sintered material or a cast material.

18. The method according to claim 13, wherein the sputtering target material is a sintered material or a cast material.

19. The method according to claim 14, wherein the sputtering target material is a sintered material or a cast material.

20. A method for suppressing arcing and splashing between a sputtering apparatus and a sputtering target material which comprises previously subjecting the sputtering target material to a friction stir processing.
